(19) United States
(12) Patent Application Publication
(10) Pub. No.: US 2019/0128952 A1
(43) Pub. Date: May 2, 2019

(54) SUBSTRATE INSPECTION APPARATUS

(71) Applicant: Tokyo Electron Limited, Tokyo (JP)

(72) Inventors: Katsuaki Sugiyama, Nirasaki-shi (JP); Atsuo Mitsui, Nirasaki-shi (JP); Yutaka Kosuga, Nirasaki-shi (JP); Kenichi Narikawa, Nirasaki-shi (JP)

(21) Appl. No.: 16/232,166

(22) Filed: Dec. 26, 2018

Related U.S. Application Data
(63) Continuation of application No. PCT/JP2017/016646, filed on Apr. 20, 2017.

(30) Foreign Application Priority Data
Jun. 28, 2016 (JP) 2016-127743

(51) Int. Cl. G01R 31/28

(52) U.S. Cl. CPC G01R 31/2834; G01R 31/2831

(57) ABSTRACT

A substrate inspection apparatus capable of suppressing deterioration of user convenience when inspecting a semiconductor device without separating the semiconductor device from a substrate is provided. A WLSLT apparatus 10, which is connected to a user controller 29 configured to control a PKGSLT apparatus 28 and configured to inspect a semiconductor device formed on a wafer W without separating the semiconductor device from the wafer W, includes a test program engine 27 configured to convert a command complying with a command protocol specific to the PKGSLT apparatus 28 into a command complying with a command protocol specific to the WLSLT apparatus 10.

### CROSS-REFERENCE TO RELATED APPLICATION

This application is a Continuation of International Application No. PCT/JP2017/016646 filed on Apr. 20, 2017, which claims the benefits of Japanese Patent Application No. 2016-127743 filed on Jun. 28, 2016. The entire disclosure of the prior application is incorporated herein by reference in its entirety.

### TECHNICAL FIELD

The various aspects and embodiments described herein pertain generally to a substrate inspection apparatus configured to inspect a semiconductor device formed on a substrate without separating the semiconductor device from the substrate.

### BACKGROUND

There is known a package system level test apparatus (hereinafter, referred to as “PKGSLT apparatus”) configured to inspect a package which is a semiconductor device as a final product while reproducing an environment (hereinafter, referred to as “mounting environment”) in which the package is mounted on a mother board. The PKGSLT apparatus is called a handler, and picks up each of a multiple number of packages put in a tray, mounts each picked package in a socket and inspects an electrical characteristic of each package. Typically, a user of the PKGSLT apparatus constructs a controller corresponding to the PKGSLT apparatus by using software and hardware to easily perform changing or setting of inspection content.

To find a defect or the like at an early stage of a manufacturing process of the semiconductor device, a prober is being developed. The prober is a substrate inspection apparatus configured to inspect a semiconductor device formed on a semiconductor wafer (hereinafter, simply referred to as “wafer”) as a substrate without separating the semiconductor device from the wafer.

The prober is equipped with: a probe card having a multiple number of pin-shaped probes; a stage configured to mount the wafer thereon and be moved up and down and in a left-right direction; and an inspection circuit which reproduces a circuit configuration in which a package is mounted, for example, a circuit configuration of a mother board. The prober inspects an electrical characteristics of the semiconductor device in the mounting environment by bringing each probe of the probe card into contact with an electrode pad or a solder bump of the semiconductor device and delivering a signal from the semiconductor device to the inspection circuit (see, for example, Patent Document 1). This kind of prober which inspects the semiconductor device in the mounting environment without separating it from the wafer is called a wafer level system level test apparatus (hereinafter, referred to as “WLSLT apparatus”).

Patent Document 1: Japanese Patent Laid-open Publication No. 2015-084398

However, when the user of the PKGSLT apparatus operates the WLSLT apparatus, since a command protocol specific to the PKGSLT apparatus and a command protocol specific to the WLSLT are different, it is required to construct a controller (a controller corresponding to the WLSLT apparatus) different from the controller corresponding to the PKGSLT apparatus in order to perform the changing or setting of inspection content in the WLSLT apparatus, which results in deterioration of the user convenience.

### SUMMARY

In view of the foregoing, exemplary embodiments provide a substrate inspection apparatus capable of suppressing deterioration of user convenience when inspecting a semiconductor device without separating the semiconductor device from a substrate.

In one exemplary embodiment, there is provided a substrate inspection apparatus connected to a controller previously operated by a user and configured to inspect a semiconductor device formed on a substrate without separating the semiconductor device from the substrate. The substrate inspection apparatus includes a converting unit configured to convert a command complying with a command protocol specific to the controller into a command complying with a command protocol specific to the substrate inspection apparatus.

According to the exemplary embodiment, the command complying with the command protocol specific to the controller previously operated by a user is converted into the command complying with the command protocol specific to the substrate inspecting apparatus configured to inspect the semiconductor device formed on the substrate without separating the semiconductor device from the substrate. Accordingly, the user is capable of controlling the substrate inspection apparatus by using the controller without needing to construct another controller different from the controller previously operated by the user. Thus, when inspecting the semiconductor device without separating it from the substrate, the deterioration of the user convenience can be suppressed.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a perspective view schematically illustrating a configuration of a WLSLT apparatus as a substrate inspection apparatus according to an exemplary embodiment;

FIG. 2 is a front view schematically illustrating the configuration of the WLSLT apparatus of FIG. 1;

FIG. 3 is a front view schematically illustrating a configuration of a probe card belonging to the WLSLT apparatus of FIG. 1;

FIG. 4 is a block diagram showing a relationship between a PKGSLT apparatus and a user controller; and

FIG. 5 is a block diagram showing a relationship between the WLSLT apparatus and the user controller according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an exemplary embodiment will be described in detail with reference to the accompanying drawings.

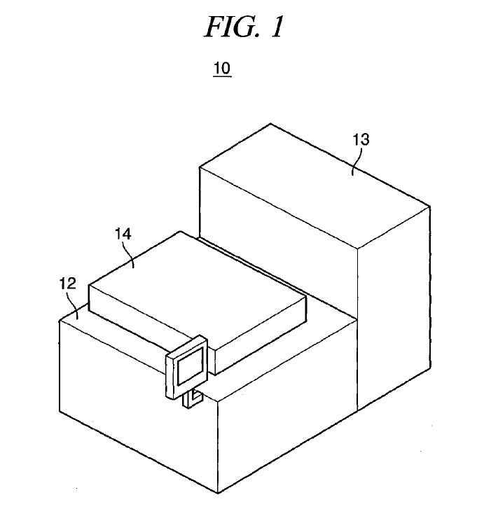

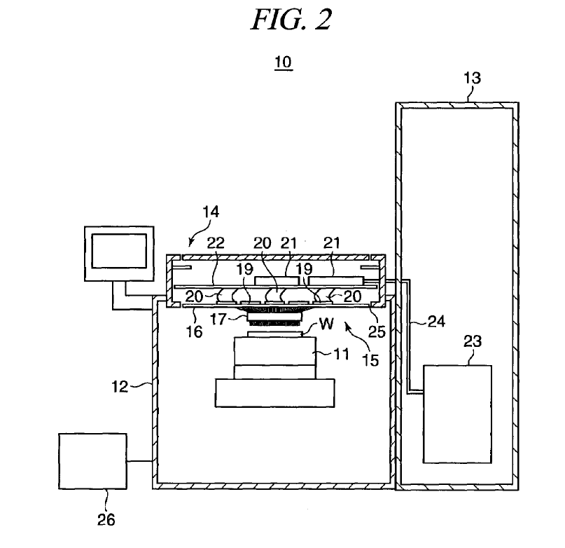

FIG. 1 is a perspective view schematically illustrating a configuration of a WLSLT apparatus as a substrate inspection apparatus according to an exemplary embodiment, and FIG. 2 is a front view of the same. FIG. 2 is a partially cross sectional view and illustrates components embedded in a main body 12, a loader 13 and a test box 14 to be described later.

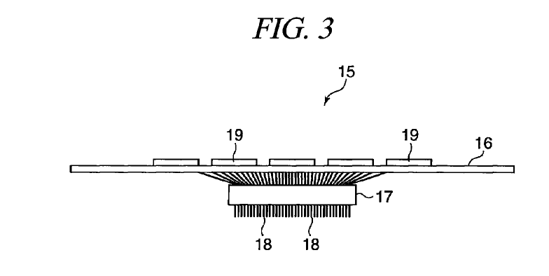

In FIG. 1 and FIG. 2, a WLSLT apparatus 10 is equipped with the main body 12 incorporating therein a stage 11 configured to mount a wafer W thereon; the loader 13 provided adjacent to the main body 12; and the test box 14 provided to cover the main body 12. This WLSLT apparatus 10 is configured to inspect an electrical characteristic of a semiconductor device as a DUT (Device Under Test) formed on the wafer W. The main body 12 has a hollow housing shape, and a probe card 15 as well as the aforementioned stage 11 is disposed within the hollow inside of the main body 12. The probe card 15 is disposed to face the stage 11. The probe card 15 faces the wafer W. The probe card 15 is equipped with a plate-shaped card board 16; and a probe head 17 provided at a bottom surface of the card board 16 facing the wafer W. As depicted in FIG. 3, the probe head 17 is equipped with a multiple number of needle-shaped probes 18 corresponding to electrode pads or solder bumps of the semiconductor devices on the wafer W.

The wafer W is fixed to the stage 11 so as not to be deviated from the stage 11. The stage 11 is configured to be moved in a horizontal direction and a vertical direction. The stage 11 adjusts relative positions of the probe card 15 and the wafer W with respect to each other and brings the electrode pads or the solder bumps of the semiconductor devices into contact with the probes 18 of the probe head 17. The loader 13 takes out the wafer W having the semiconductor devices formed thereon from a FOUP (not shown) as a transfer receptacle and places the taken wafer W on the stage 11 within the main body 12. Further, the loader 13 separates the wafer W from the stage 11 after being subjected to a wafer level system level test, and then, accommodates the wafer W back into the FOUP.

Formed at the card board 16 of the probe card 15 is a card-side inspection circuit 19 which reproduces a part of a circuit configuration in which a package which is a semiconductor device as a final product separated from the wafer W is mounted, for example, a circuit configuration of a mother board (see FIG. 3), and this card-side inspection circuit 19 is connected to the probe head 17. When the probes 18 of the probe head 17 respectively come into contact with the corresponding electrode pads or solder bumps of the semiconductor devices of the wafer W, each probe 18 supplies a power to a power source of the corresponding semiconductor device and delivers a signal from the semiconductor device to the card-side inspection circuit 19.

The test box 14 includes a harness 20 as a wiring; an inspection control unit or a recording unit (both are not shown); and a test board 22 on which a box-side inspection circuit 21 which reproduces a part of the circuit configuration of the mother board is formed. The harness 20 connects the test board 22 of the test box 14 and the card board 16 of the probe card 15 and delivers a signal from the card-side inspection circuit 19 to the box-side inspection circuit 21. In the WLSLT apparatus 10, by replacing the test board 22 of the test box 14, it is possible to reproduce a part of a circuit configuration of any of multiple kinds of mother boards.

The loader 13 incorporates therein a base unit 23 including a power source, a controller and a simple measurement module. The base unit 23 is connected to the box-side inspection circuit 21 via a wiring 24, and the controller instructs the box-side inspection circuit 21 to start an inspection of the electrical characteristic of the semiconductor device. In the WLSLT apparatus 10, though the card-side inspection circuit 19 formed on the card board 16 and the box-side inspection circuit 21 formed on the test board 22 reproduce the different parts of the circuit configuration of the mother board, the base unit 23 reproduces a circuit configuration commonly shared by the multiple kinds of mother boards. Thus, the card board 16, the test board 22 and the base unit 23 reproduce in cooperation the entire mother board in which the package is mounted. That is, the card board 16, the test board 22 and the base unit 23 reproduce a mounting environment in which the package is mounted on the mother board.

In the WLSLT apparatus 10, when inspecting the electrical characteristic of the semiconductor device, the inspection control unit of the box-side inspection circuit 21 outputs data to the card-side inspection circuit 19, and determines based on an electric signal output from the card-side inspection circuit 19 whether the output data are appropriately processed by the card-side inspection circuit 19 which is connected with the semiconductor device. Further, in the WLSLT apparatus 10, though the test board 22 of the test box 14 and the card board 16 of the probe card 15 are connected by the harness 20, a bottom-surface opening 25 having a size corresponding to the card board 16 is provided at a bottom surface of the test box 14, and the test board 22 and the card board 16 face each other. With this configuration, the test board 22 and the card board 16 can be disposed adjacent to each other, and a length of the harness 20 can be set as short as possible. As a result, in the wafer level system level test, an influence of the length of the harness 20, for example, an influence of a variation of a wiring capacity can be suppressed, so that the wafer level system level test can be carried out in the mounting environment which is very close to a working environment of a computer as a real machine having a function extension card or the mother board.

Further, the WLSLT apparatus 10 is equipped with a control unit 26 configured to control operations of the individual components of the WLSLT apparatus 10. The control unit 26 is implemented by a memory or a CPU, and constitutes a test program engine 27 (converting unit) to be described later which is configured to execute various kinds of programs.

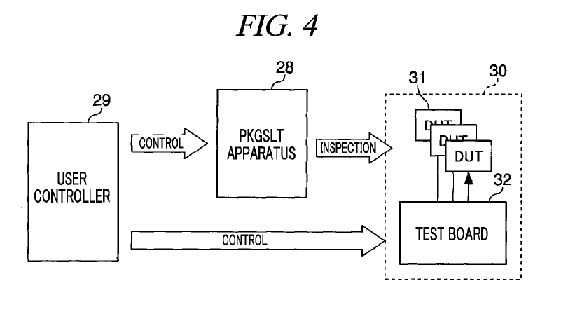

FIG. 4 is a block diagram illustrating a relationship between a PKGSLT apparatus and a user controller. Further, the PKGSLT apparatus typically incorporates therein a test site in which a test board or a socket in which a package as the DUT is mounted is placed. In FIG. 4, however, the PKGSLT apparatus and the test site are illustrated to be provided separately from each other for the convenience of explanation.

In FIG. 4, a PKGSLT apparatus 28 is connected to a user controller 29. The user controller 29 is specific to the PKGSLT apparatus 28 and is built up by using software and hardware. Further, though the user controller 29 is built by a user, it may be constructed by a vendor of the PKGSLT apparatus 28.

The user performs the changing or the setting of inspection content of the package in the user controller 29, and the user controller 29 controls the PKGSLT apparatus 28 by outputting various kinds of commands to the PKGSLT apparatus 28 in response to the changing or the setting of the inspection content of the package. The various commands outputted by the user controller 29 are commands which comply with a command protocol specific to the PKGSLT apparatus 28. Further, as stated above, since the user controller 29 is constructed to correspond to the PKGSLT apparatus 28, the various kinds of commands outputted by the user controller 29 may also be regarded as commands complying with a command protocol specific to the user controller 29. The PKGSLT apparatus 28 which has received the various kinds of commands from the user controller 29 picks each DUT (package) 31 up and mounts the picked DUT 31 in a socket (not shown) in a test site 30, and inspects an electrical characteristic of each DUT 31 according to the commands. The socket is mounted to the test board 32 and configured to deliver a signal from each DUT 31 to an inspection circuit (not shown) of the test board 32. Further, the test board 32 is directly connected to the user controller 29, and the user controller 29 controls the test board 32 by outputting various kinds of commands to the test board 32 directly.

When the user of the PKGSLT apparatus 28 operates the WLSLT apparatus 10, since the command protocol specific to the PKGSLT apparatus 28 and a command protocol specific to the WLSLT apparatus 10 are different from each other, the user is not able to control the WLSLT apparatus 10 by using the user controller 29 even if the user controller 29 is connected to the WLSLT apparatus 10. In the present exemplary embodiment, the WLSLT apparatus 10 is equipped with the test program engine 27 to solve this problem.

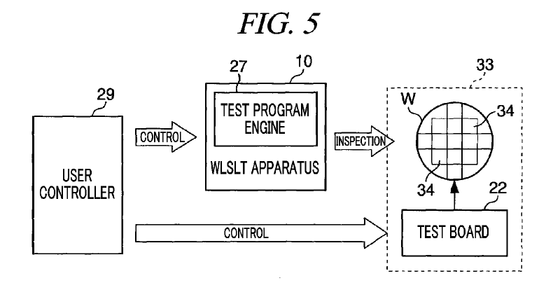

FIG. 5 is a block diagram showing a relationship between the WLSLT apparatus and the user controller according to the present exemplary embodiment. The WLSLT apparatus 10 incorporates therein, for example, a test site 33 in which the test board 22 and the probe card 15 having the probes 18 to be brought into contact with individual semiconductor devices as the DUTs formed on the wafer W are placed. In FIG. 5, for the convenience of explanation, the WLSLT apparatus 10 and the test site 33 are illustrated to be provided separately from each other, as in FIG. 4.

In FIG. 5, the WLSLT apparatus 10 is connected to the user controller 29 and has the test program engine 27 as stated above. The test program engine 27 is an engine capable of executing various kinds of programs in the WLSLT apparatus 10. The user loads a required program to the test program engine 27 to implement a required function in the WLSLT apparatus 10. In the present exemplary embodiment, a command conversion program is loaded to the test program engine 27. The command conversion program is a program in which a command complying with the command protocol specific to the PKGSLT apparatus 28 is converted into a command complying with the command protocol specific to the WLSLT apparatus 10. The test program engine 27 to which the command conversion program is loaded serves as a command converting unit.

To elaborate, if the user performs the changing or the setting of the inspection content of the semiconductor devices in the user controller 29, the user controller 29 outputs various kinds of commands complying with the command protocol specific to the PKGSLT apparatus 28 to the WLSLT apparatus 10 in response to the changing or the setting of the inspection content of the semiconductor devices. These outputted commands include, by way of example, but not limitation, an individual measurement start command indicating a start of measurement of the electrical characteristic of each of the DUTs (semiconductor devices) 34; an overall exclusion command indicating determination upon whether or not the measurement of the electrical characteristic of each DUT 34 is to be performed; an individual exclusion command for excluding a preset DUT 34 from the targets of the measurement of the electrical characteristic; an overall setup command for setting each semiconductor device as the measurement target; an individual setup command specifying the DUTs 34 as the measurement targets of the electrical characteristics individually; an individual power source control command indicating an on/off operation of individual power sources of the DUTs 34; and an overall power source control command indicating whether to turn on or off the power sources of the individual DUTs 34, and the card-side inspection circuit 19 of the card board 16 or the box-side inspection circuit 21 of the test board 22.

In the WLSLT apparatus 10 having received the various commands from the user controller 29, the test program engine 27 analyzes the various kinds of commands complying with the command protocol specific to the PKGSLT apparatus 28, and, then, converts these commands into various kinds of commands complying with the command protocol specific to the WLSLT apparatus 10. In response to the converted various kinds of commands, the control unit 26 allows each probe 18 of the probe card 15 into contact with the corresponding DUT 34 in the test site 33 to perform the inspection of the electrical characteristic of the corresponding DUT 34. Further, in the WLSLT apparatus 10, the test board 22 is directly connected to the user controller 29, and the user controller 29 controls the test board 22 by outputting various kinds of commands to the test board 22 directly, as in the PKGSLT apparatus 28.

Further, the WLSLT apparatus 10 is equipped with an interface through which the user is capable of constructing a test program, for example, a PC unit (not shown). Though it is typical that the user constructs the command conversion program in the PC unit, it is also possible for the vendor to construct the command conversion program and store the command conversion program in a memory of the control unit 26 before the WLSLT apparatus 10 is shipped. Further, since the test program engine 27 is capable of executing the various kinds of programs, before the inspection of the semiconductor device is performed, a test program for checking, for example, whether the inspection of the semiconductor device whose content is changed can be performed may be executed. Thus, the user can perform this checking upon whether the inspection of the semiconductor device whose content is changed can be performed in the WLSLT apparatus 10 which actually performs the inspection of the semiconductor device whose content is changed, not in other apparatus. Thus, it is not required to consider an apparatus difference in a debugging operation of the test program, so that efficiency of the debugging operation can be improved.

According to the present exemplary embodiment, since the command complying with the command protocol specific to the PKGSLT apparatus 28 (user controller 29) is converted to the command complying with the command protocol specific to the WLSLT apparatus 10 by the test program engine 27, it is possible, when using the WLSLT apparatus 10, to control the WLSLT apparatus 10 by using the user controller 29 without needing to construct another user controller 29 different from the user controller 29. Thus, deterioration of user convenience can be suppressed when inspecting the semiconductor device without separating the semiconductor device from the wafer W. Further, since the PKGSLT apparatus 28 and the WLSLT apparatus 10 can be controlled by the same user controller 29, the user can operate both of the PKGSLT apparatus 28 and the WLSLT apparatus 10 without needing to be aware of their difference. Therefore, the user convenience can be further bettered.

In the present exemplary embodiment, the function of converting the command complying with the command protocol specific to the PKGSLT apparatus 28 into the command complying with the command protocol specific to the WLSLT apparatus 10 can be implemented by loading the command conversion program to the test program engine 27. That is, new hardware is not necessary to implement the function of converting the command, so that unnecessary cost-up or complication of the structure can be suppressed in the WLSLT apparatus 10.

So far, the exemplary embodiment has been described. However, the exemplary embodiment is not limited thereto.

By way of example, the aforementioned test program engine 27 implements the function of converting the command complying with the command protocol specific to the PKGSLT apparatus 28 into the command complying with the command protocol specific to the WLSLT apparatus 10. However, it may also be possible to, by changing the command conversion program, convert a command complying with a command protocol specific to a WLSLT apparatus of another vendor, for example, into the command complying with the command protocol specific to the WLSLT apparatus 10. Thus, since the WLSLT apparatus of the another vendor and the WLSLT apparatus 10 can be controlled by the same user controller, the user can operate either apparatus without needing to be aware of a vendor difference of the WLSLT apparatus.

Furthermore, though the card-side inspection circuit 19 or the box-side inspection circuit 21 reproduces a part of the circuit configuration of the mother board, the circuit configuration reproduced by the card-side inspection circuit 19 or the box-side inspection circuit 21 may not be limited to the circuit configuration of the mother board. That is, the circuit configuration reproduced by the card-side inspection circuit 19 or the box-side inspection circuit 21 is not particularly limited as long as it is a circuit configuration in which the semiconductor device is mounted. Further, the configuration of the semiconductor device is not particularly limited, either. For example, if the circuit configuration reproduced by the card-side inspection circuit 19 is a circuit configuration of an extension card, the semiconductor device may be a MPU (Main Processing Unit). As another example, if the circuit configuration reproduced by the card-side inspection circuit 19 or the box-side inspection circuit 21 is the circuit configuration of the mother board as stated above, the semiconductor device may be a DRAM, an APU (Accelerated Processing Unit) or a GPU (Graphics Processing Unit). Further, if the circuit configuration reproduced by the card-side inspection circuit 19 or the box-side inspection circuit 21 is a circuit configuration of a television, the semiconductor device may be a RF tuner.

Furthermore, it may be possible to supply a recording medium having stored thereon a program code of software which implements the function of the above-described exemplary embodiment to the control unit 26. As the CPU of the control unit 26 reads out and executes this program code stored in the recording medium, the objective of the present disclosure can be accomplished.

In such a case, the program code itself, which is read out from the recording medium, realizes the above-described function of the exemplary embodiment, and the program code and the recording medium storing therein the program code constitute the present disclosure.

Furthermore, the recording medium for supplying the program code is not particularly limited as long as it is capable of storing the program code therein. By way of non-limiting example, the recording medium may be a RAM, a NV-RAM, a Floppy (registered trademark) disk, a hard disk, a magneto-optical disk, an optical disk such as a CD-ROM, a CD-R, a CD-RW, a DVD (DVD-ROM, DVD-RAM, DVD-RW, DVD+RW), a magnetic tape, a non-volatile memory card, other types of ROMs, etc. Alternatively, the program code may be supplied to the control unit 26 by being downloaded from a non-illustrated another computer or database connected to Internet, a commercial network or a local area network.

In addition, the present disclosure includes not only the aforementioned case where the function of the exemplary embodiment is implemented as the CPU executes the read program code but also a case where an OS (operating system) or the like working on the CPU performs a part or the whole of an actual processing based on an instruction of the program code and the function of the aforementioned exemplary embodiment is realized by this processing.

Moreover, the present disclosure also includes a case where, after the program code read out from the recording medium is recorded in a memory of a function extension card or a function extension unit connected to the control unit 26, a CPU or the like belonging to the function extension card or the function extension unit performs a part or the whole of the actual processing based on an instruction of the program code and the function of the above-described exemplary embodiment is realized by this processing.

The program code may be in the form of an object code, a program code executed by an interpreter, a script data supplied to the OS, or the like.

This application claims priority to Japanese Patent Application No. 2016-127743, filed on Jun. 28, 2016, which application is hereby incorporated by reference in its entirety.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate inspection apparatus connected to a controller previously operated by a user and configured to inspect a semiconductor device formed on a substrate without separating the semiconductor device from the substrate, the substrate inspection apparatus comprising:
a converting unit configured to convert a command complying with a command protocol specific to the controller into a command complying with a command protocol specific to the substrate inspection apparatus.

2. The substrate inspection apparatus of claim 1,
wherein the controller controls a package inspection apparatus configured to inspect a package which is a semiconductor device as a final product.

3. The substrate inspection apparatus of claim 1, further comprising:
a program engine configured to execute a program,
wherein the converting unit is implemented by loading, to the program engine, a program in which the command is converted.

4. The substrate inspection apparatus of claim 3,
wherein the program engine has a control function of controlling the substrate inspection apparatus and a test program executing function of executing a test program.
